(19) United States
(12) Patent Application Publication
(10) Pub. No.: US 2009/0230309 A1
(43) Pub. Date: Sep. 17, 2009

(54) METHOD FOR MANUFACTURING A SOLID STATE RADIATION DETECTOR, AND RADIATION IMAGING SYSTEM

(75) Inventor: Katsuhiro KOHDA, Ashigarakami-gun (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM CORPORATION, Tokyo (JP)

(21) Appl. No.: 12/404,685

(22) Filed: Mar. 16, 2009

(30) Foreign Application Priority Data
Mar. 14, 2008 (JP) 2008-065123

(51) Int. Cl. G01T 1/24; H01L 21/00

(52) U.S. Cl. 250/370.09; 438/69; 257/E21.001

(57) ABSTRACT

A method for manufacturing a solid state radiation detector having an active matrix layer, in which a great number of reading elements are arranged, and a radiation photoconductive layer that generates electric charges when irradiated by electromagnetic waves that bear image information, provided such that the electric charges are read out by the active matrix layer, is characterized by: the active matrix layer being formed directly on the radiation photoconductive layer.

### BACKGROUND OF THE INVENTION

1. Field of the Invention

The present invention is related to a solid state radiation detector which is suited to application to radiation imaging apparatuses, such as X-ray imaging apparatuses. More specifically, the present invention is related to a method for manufacturing a direct conversion type solid state radiation detector.

2. Description of the Related Art

Currently, various X-ray imaging apparatuses that employ solid state radiation detectors (having semiconductors as the main portions thereof) as X-ray image information recording means have been proposed and are in practical use in the field of X-ray imaging for the purposes of medical diagnosis and the like. The solid state detectors detect X-rays which have passed through subjects, to obtain image signals that represent X-ray images of the subjects.

Various types of solid state detectors to be employed by the X-ray imaging apparatuses have been proposed. From the viewpoint of a charge generating process for converting X-rays to electric charges, there are solid state detectors of the optical conversion type (indirect conversion type), and solid state detectors of the direct conversion type. In a solid state detector of the indirect conversion type, fluorescence generated from phosphors due to the irradiation of radiation is detected by an optically photosensitive layer. Signal charges obtained by the optically photosensitive layer are temporarily accumulated. Then, the accumulated charges are converted to image signals (electric signals) and output. In a solid state detector of the direct conversion type, electric charges are generated within a photoconductive layer due to irradiation of X-rays. These signal charges are collected by charge collecting electrodes, and temporarily accumulated in a charge accumulating section. The accumulated charges are converted into electric signals and then output. The main portion of a solid state of the direct conversion type is the photoconductive layer and the charge collecting electrodes.

There are two main types of methods for reading out accumulated electric charges as well. One is an optical readout method that irradiates detectors with readout light (readout electromagnetic waves) to perform readout. The other is a TFT readout method that scans and drives TFT'S (Thin Film Transistors) which are connected to charge accumulating sections, to read out the accumulated charges.

Of the two types of readout methods, the TFT readout method (hereinafter, simply referred to as the TFT method) does not require a scintillator layer for temporarily converting radiation to light. Therefore, there is an advantage that the sharpness of images read out by the TFT method is superior. Amorphous selenium (a-Se) is commonly employed as the radiation photoconductive layer, because this material has the advantages that it has high dark current resistance and superior response speed (refer to U.S. Pat. No. 5,319,206 and Japanese Unexamined Patent Publication No. 2001-320035, for example). Solid state detectors that employ the TFT method and amorphous selenium radiation photoconductive layers are widely used in conjunction with medical diagnostic apparatuses.

However, the atomic number of a-Se is small, and the density thereof is low (at 4.3 g/cm³). Therefore, the ability of a-Se to absorb X-rays is poor, and there is a problem that radiation photoconductive layers formed by a-Se need to be of substantial thicknesses (1 mm thick, for example), in order to obtain sufficient absorption of X-rays. The a-Se layers may be formed to be even thicker in order to obtain further X-ray absorption qualities. However, as the layers get thicker, higher voltages (greater than 10 kV, for example) need to be applied to maintain electrical fields therein. Applying high voltages lead to an increased likelihood that shorting will occur, and there is a problem that safety becomes difficult to secure. In addition, a-Se is likely to become crystallized at temperatures of 50° C. or greater, which leads to decreased sensitivity. As described above, there are restrictive conditions regarding the use of a-Se photoconductive layers.

The use of photoconductive materials of which the main elements have high atomic numbers and high densities, such as CdTe (density: 5.9 g/cm³), PbI₂ (density: 6.2 g/cm³), and PbO (density: 9.8 g/cm³) instead of a-Se is being considered in view of the foregoing problem. In addition, the main element of Bi₁₂XO₂₀ (wherein X is one of Si, Ge, and Ti, hereinafter, simply referred to as BXO) also has a high atomic number and a density of 9.2 g/cm³. Therefore, stability and high X-ray absorption properties are expected from BXO. U.S. Patent Application Publication No. 20050214581 discloses a method for manufacturing a polycrystalline material (or a sintered material) of BXO at a size of approximately 40 cm by 40 cm for use in medical image diagnosis at low cost.

In cases that a-Se, HgI₂, PbI₂ or Pbo are employed as the radiation photoconductive layer in solid state radiation detectors that employ the TFT method, the photoconductive materials are electrically joined with TFT's by producing the TFT's on a glass substrate, and then growing the photoconductive materials thereon by a vapor phase growth method.

In the case that BXO is employed as the material of the radiation photoconductive layer, high temperatures (greater than or equal to 600° C., for example) are required to form BXO. Therefore, if BXO is to be formed on TFT's, there is a problem that the high temperatures destroy transistors, which are TFT elements (the upper temperature limit for TFT elements is approximately 300° C.).

A similar problem occurs in cases that CdTe or CdTe doped with Zn (CdZnTe, hereinafter, referred to as CZT) is employed as the material of the radiation photoconductive layer in solid state radiation detectors that employ the TFT method. That is, in cases that CdTe and CZT are to be formed by the vapor phase growth method, it is necessary for substrate temperatures to be approximately 400° C. Therefore, if the radiation photoconductive layers of CdTe or CZT are formed on TFT's, the TFT's will be destroyed.

Japanese Unexamined Patent Publication No. 11(1999)-287862 discloses a method that avoids this problem. In this method, films of CdTe and the like are formed in advance. Then, the films are adhesively attached to TFT's by conductive adhesive or the like, and electrically connected to TFT electrodes corresponding to each pixel.

In solid state radiation detectors that employ the TFT method, if a single adhesive film is employed to form connections, all of the pixels become connected to each other. Therefore, readout of single pixels becomes impossible, and information cannot be obtained as two dimensional images. Accordingly, the method disclosed in Japanese Unexamined Patent Publication No. 11(1999)-287862 involves adhesively attaching the films to each pixel, one by one. However, it is extremely difficult to adhesively attach films to each pixel across a 40 cm by 40 cm size without positional shifting. Production yields will decrease, and high cost will be incurred. In addition, after adhesive attachment, problems such as detachment are likely to occur due to vibration or the passage of time, and these solid state radiation detectors have a problem of reduced reliability over time.

### SUMMARY OF THE INVENTION

The present invention has been developed in view of the foregoing circumstances. It is an object of the present invention to provide a method for manufacturing a solid state radiation detector equipped with a radiation photoconductive layer having extremely high thermal stability, which can be manufactured at low cost without positioning the material of the photoconductive layer for each pixel when establishing electrical connections between the material and TFT'S.

A method for manufacturing a solid state radiation detector of the present invention is a method for manufacturing a solid state radiation detector having an active matrix layer, in which a great number of reading elements are arranged, and a radiation photoconductive layer that generates electric charges when irradiated by electromagnetic waves that bear image information, provided such that the electric charges are read out by the active matrix layer, characterized by:

the active matrix layer being formed directly on the radiation photoconductive layer.

Here, the phrase “formed directly” refers to a state in which the active matrix layer is provided on the radiation photoconductive layer in direct contact, without any substances, such as a conductive adhesive, interposed therebetween.

It is desirable for the radiation photoconductive layer to be of a composite inorganic material. It is desirable for the composite inorganic material to be at least one of: CdTe, CdZnTe, Bi₁₂SiO₂₀; Bi₁₂GeO₂₀; and Bi₁₂TiO₂₀ A radiation imaging system of the present invention is characterized by housing a solid state radiation detector which is produced by the above manufacturing method.

A solid state radiation detecting cassette is characterized by housing a solid state radiation detector which is produced by the above manufacturing method.

The method for manufacturing a solid state radiation detector of the present invention is a method for manufacturing a solid state radiation detector equipped with the active matrix layer, in which a great number of reading elements are arranged; and the radiation photoconductive layer that generates electric charges when irradiated by electromagnetic waves that bear image information, provided such that the electric charges are read out by the active matrix layer. The active matrix layer is formed directly on the radiation photoconductive layer. Therefore, it is not necessary to position the radiation photoconductive layer for each pixel of the reading elements when establishing electrical connections therebetween. Accordingly, a solid state radiation detector having a radiation photoconductive layer with extremely high thermal stability can be manufactured at low cost.

In addition, it is possible to manufacture the solid state radiation detector of the present invention without glass substrates, which are commonly used in conventional solid state radiation detectors. Accordingly, a radiation imaging system that houses the solid state radiation detector of the present invention can be formed to be lightweight, and conveyance of a built in movable imaging unit is facilitated. Particularly in the case that the radiation imaging system is of the cassette type, a solid state radiation detecting cassette that houses the solid state radiation detector of the present invention is extremely lightweight compared to conventional cassettes, and is superior in portability.

### BRIEF DESCRIPTION OF THE DRAWINGS

FIG. 1 is a schematic sectional view that illustrates the structure of a single pixel of a solid state radiation detector which is produced by the manufacturing method of the present invention.

FIG. 2 is a schematic plan view that illustrates the structure of a single pixel of a solid state radiation detector which is produced by the manufacturing method of the present invention.

FIGS. 3A, 3B, 3C, 3D, 3E, 3F, and 3G are schematic diagrams that illustrate a portion of the manufacturing steps of the solid state radiation detector of the present invention.

FIG. 4 is a schematic sectional diagram that illustrates a solid state radiation detector of a top gate structure.

FIGS. 5A, 5B, and 5C are schematic diagrams that illustrate a portion of the manufacturing steps of the solid state radiation detector of the top gate structure.

FIG. 6 is a plan view of a solid state radiation detecting cassette according to a second embodiment of the present invention, with an upper shell half omitted.

FIG. 7 is a sectional view of the radiation detecting cassette of FIG. 6, taken along line I-I, including the upper shell half.

### BEST MODE FOR CARRYING OUT THE INVENTION

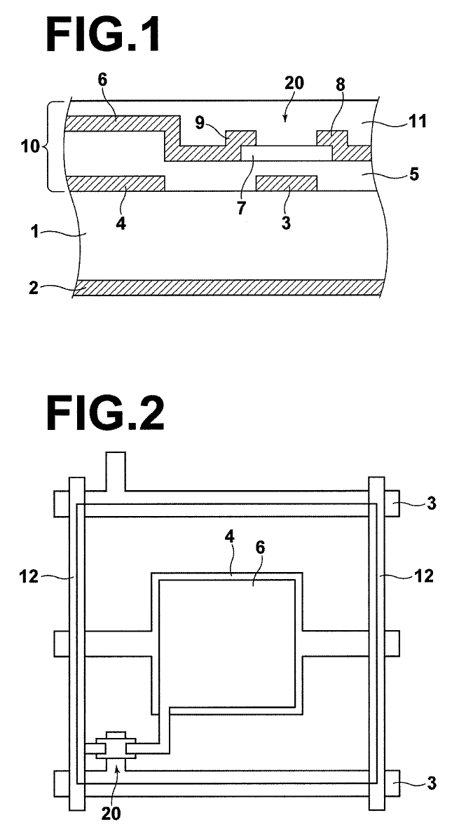

Hereinafter, a method for manufacturing a solid state radiation detector of the present invention will be described with reference to the drawings. FIG. 1 is a schematic sectional view that illustrates the structure of a single pixel of the solid state radiation detector which is produced by the manufacturing method of the present invention. FIG. 2 is a schematic plan view of the single pixel of the solid state radiation detector.

As illustrated in FIG. 1, the solid state radiation detector which is produced by the manufacturing method of the present invention is equipped with a radiation photoconductive layer 1, that generates electric charges when irradiated by electromagnetic waves that bear image information, provided such that the electric charges are read out by an active matrix layer 10. The active matrix layer 10, in which a great number of TFT switches are arranged, is provided on the radiation photoconductive layer 1. A biasing electrode 2 (a common voltage applying electrode) is formed on the side of the radiation photoconductive layer 1 on which the active matrix layer 10 is not formed. The radiation photoconductive layer 1 generates electric charges (electrons and positive holes) in the interior thereof when radiation (electromagnetic waves) such as X-rays is irradiated thereon. That is, the radiation photoconductive layer 1 has electromagnetic wave conductivity, and converts image information borne by radiation into electric charge information.

Portions of the active matrix layer 10 corresponding to each pixel are constituted by: a gate electrode 3; a charge collecting electrode 4; a gate insulating film 5; a charge accumulating capacitor electrode 6 (CS electrode); a semiconductor layer 7; a source electrode 8; a drain electrode 9; and a interlayer insulating film 11, which is a smooth film. The gate electrode 3, the gate insulating film 5; the source electrode 8; the drain electrode 9; the semiconductor layer 7 and the like constitute a TFT 20 (Thin Film Transistor, hereinafter, referred to as TFT switch 20). The TFT switch 20 is a reading element. The source electrode 8 and the drain electrode 9 are connected to a data line 12 and the charge accumulating capacitor electrode 6, respectively. The semiconductor layer 7 functions to connect the source electrode 8, the drain electrode 9, and the gate electrode 3. Data line 12 which are connected to the gate electrode 3 and the source electrode 8 are electrode lines which are arranged in a lattice as illustrated in FIG. 2, and the TFT switches 20 are formed at the intersections thereof.

In this solid state radiation detector, if radiation is irradiated onto the radiation photoconductive layer 1 while an electric field is formed between the biasing electrode 2 and the charge collecting electrodes 4, charge pairs are generated within the radiation photoconductive layer 1. Latent charges corresponding to the amount of charge pairs are accumulated in the charge accumulating capacitor electrodes 6. When reading out the accumulated latent charges, the TFT's are sequentially driven, to cause image signals based on the latent charges corresponding to each pixel to be output through output lines. The image signals are detected by a signal detecting means, to read out an electrostatic latent image borne by the latent charges.

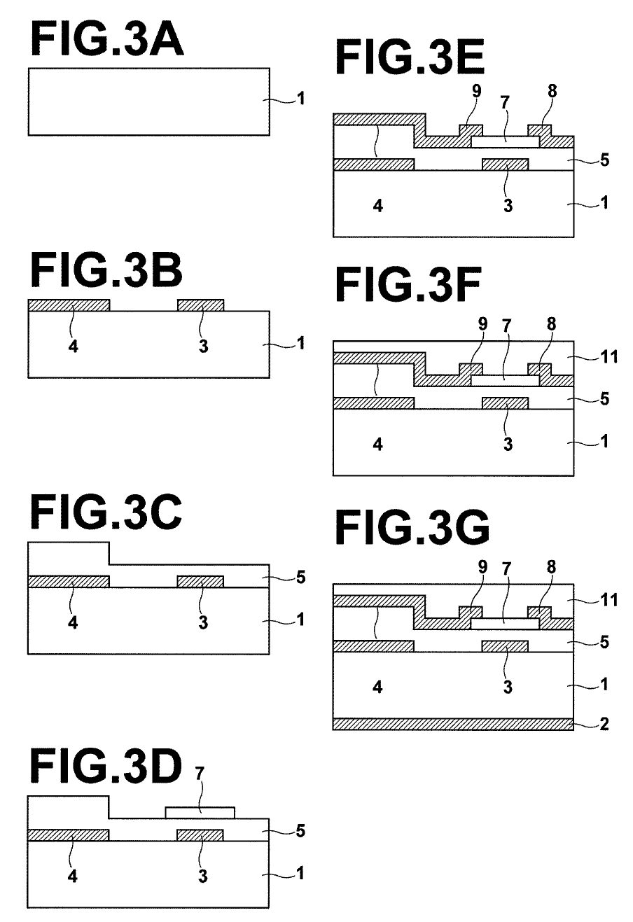

In the method for manufacturing a solid state radiation detector of the present invention, the active matrix layer 10 illustrated in FIG. 1 is directly formed on the radiation photoconductive layer 1. Details of the method for manufacturing the solid state radiation detector such that the two layers are directing joined will be described with reference to FIGS. 3A through 3G.

First, the radiation photoconductive layer 1 is produced (FIG. 3A). It is preferable for the material of the radiation photoconductive layer 1 to be a composite inorganic material. It is preferable for the composite inorganic material to be at least one of CdTe, CZT, Bi₁₂SiO₂₀, Bi₁₂GeO₂₀, and Bi₁₂TiO₂₀. Note that other composite inorganic materials, such as HgI₂, PbI₂, and PbO also obviate restrictions with regard to the temperature of a substrate during film growth by the vapor phase growth method. Therefore, by forming these films at higher temperatures, the crystallization properties of the photoconductive layer are improved, and obtainment of superior performance is facilitated. TiBr and BiI₃ are other materials that can be employed.

In the case that the radiation photoconductive layer 1 is to be produced from CdTe or CZT, the radiation photoconductive layer 1 may be formed as a single crystal film by the Bridgeman method, the gradient freeze method, the travel heating method or the like. In the case that the radiation photoconductive layer 1 is to be a polycrystalline film, the MOCVD method may be employed. The MOCVD method is suited for growing films on substrates having large areas. Organic cadmium, such as dimethyl cadmium (DMCd); organic tellurium, such as diethyl tellurium (DETe) and diisopropyl tellurium (DiPTe); and organic zinc, such as diethyl zinc (DEZn), diisopropyl zinc (DiPZn), and dimethyl zinc (DMZn) may be employed as raw materials to form films at temperatures of 400° C. to 500° C. by the MOCVD method. Note that the screen printing/sintering method, the close space sublimation method, the electrocrystallization method, and the spray method are alternate film forming methods that may be used to form films of CdTe and CZT. In the case that the radiation photoconductive layer 1 is formed by CdTe or CZT, it is preferable for the thickness thereof to be approximately 0.5 mm.

In the case that the radiation photoconductive layer 1 is to be produced from Bi₁₂SiO₂₀, Bi₁₂GeO₂₀, or Bi₁₂TiO₂₀, a BXO precursor liquid may be obtained by causing a bismuth salt (bismuth nitrate or bismuth acetate) and a metal alchoxide(an alchoxide( of Ge, Si, or Ti, more specifically, Ge(O—CH₃)₄, Ge(O—C₂H₅)₄, Ge(O-iC₃H₇)₄, Si(O—CH₃)₄, Si(O—C₂H₅)₄, Si(O-iC₃H₇)₄, Ti(O—CH₃)₄, Ti(O—C₂H₅)₄, Ti(O-iC₃H₇)₄, or the like) to react under acidic conditions. The BXO precursor liquid may be coated onto a substrate and dried. The dried BXO film or the dried BXO precursor film may be sintered at 800° C. to 900° C., to form the radiation photoconductive layer 1.

Alternate methods for forming the radiation photoconductive layer 1 include: an aerosol deposition method (AD method), in which BXO powder, which is prepared in advance in a vacuum, is mixed with a carrier gas, then the carrier gas having the BXO powder mixed therein is sprayed onto a substrate such that the BXO powder accumulates thereon in a vacuum; a press sintering method, in which BXO powder is formed into a film by pressing with high pressure using a pressing machine, and sintering the obtained film; a green sheet method, in which a green sheet (a film including binder) is formed by coating BXO powder with a binder, then the green sheet is sintered to remove the binder and to sinter the BXO powder.

An example of a method for adjusting the BXO powder to be employed in the above production methods involves the steps of: causing a bismuth salt and a metal alkoxide to undergo hydrolysis under acidic conditions to obtain a BXO precursor liquid; concentrating the obtained BXO precursor liquid to form a gel; and sintering the BXO precursor in gel form to obtain the BXO powder. Another example of a method for adjusting the BXO powder involves the steps of: mixing bismuth oxide (Bi₂O₃) and MO₂ (silicon oxide, germanium oxide, titanium oxide); and obtaining the BXO powder by a solid phase reaction that occurs when the mixture is preliminarily fired at 800° C., for example.

The gate electrodes 3 are formed by sputtering a metal film of Ta, Al and the like to a desired thickness (300 nm, for example) onto the radiation photoconductive layer 1 produced by the aforementioned methods by sputtering, then patterning the formed metal film into desired shapes. The charge collecting electrodes 4 are formed by forming a non crystalline transparent conductive oxide film is formed on the radiation photoconductive layer 1 to a desired thickness (200 nm, for example) by sputtering vapor deposition or the like, then patterning the formed non crystalline transparent conductive oxide film into desired shapes (FIG. 3B).

Next, the gate insulating film 5 is formed by SiNₓ, SiOₓ so as to cover the gate electrodes 3 and the charge collecting electrodes 4 across substantially the entire surface of the radiation photoconductive layer 1 by the CVD (Chemical Vapor Deposition) method or the like to a desired thickness (350 nm, for example), as illustrated in FIG. 3C. Note that the material of the gate insulating film 5 is not limited to SiNₓ and SiOₓ. Alternatively, an anodized film obtained by anodizing the gate electrodes 3 and the charge collecting electrodes 4 may be employed as the gate insulating film 5.

Next, a-Si, for example, is formed as a film having a thickness of approximately 40 nm by the CVD method or the like, and patterned into desired shapes, such that the semiconductor layer 7 is provided above the gate electrodes 3 with the gate insulating film 5 interposed therebetween (FIG. 3D).

Thereafter, a metal film of Ta, Al, or the like is formed as a film on the semiconductor layer 7 at a thickness of approximately 300 nm, then patterned into desired shapes, to form the source electrodes 8 and the drain electrodes 9 (FIG. 3E).

Acrylic resin having photosensitive properties, for example, is formed as a film having a thickness of approximately 3 μm to cover substantially the entire surface of the radiation photoconductive layer 1, on which the TFT switches 20 have been formed in the manner described above, to form the interlayer insulating layer 11 (FIG. 3F).

Finally, the biasing electrode 2 is formed on the surface of the radiation photoconductive layer 1 opposite that on which the TFT switches 20 are formed, by depositing Au, Al, or the like by the vacuum vapor deposition method to a desired thickness (200 nm, for example), as illustrated in FIG. 3G.

Note that the structural strength of the solid state radiation detector is insufficient in this state. Therefore, a substrate is fixed to the lower surface of the biasing electrode 2 with adhesive or the like, to reinforce the solid state radiation detector. Here, because only a predetermined degree of structural strength will suffice, it is not necessary to employ heavy and easily breakable glass substrates which are frequently used in conventional solid state radiation detectors. Instead, lightweight metal plates, such as aluminum plates and magnesium alloy plates, resin plates, and CFRP's (Carbon Fiber Reinforced Plastics) may be favorably employed. By using these materials as the substrate, the solid state radiation detector of the present invention can be formed to be much more lightweight than conventional solid state detectors. In the case that the solid state radiation detector of the present invention is hosed within a cassette to be described later, the cassette will be superior in portability.

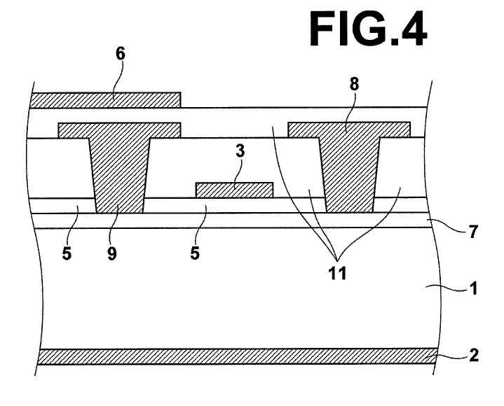

The above embodiment was described as a bottom gate structure (reverse staggered structure), in which the gate electrodes 3 of the active matrix layer 10 are positioned beneath the semiconductor layer 7. Alternatively, the solid state radiation detector of the present invention may be of a top gate structure (staggered structure), in which the gate electrodes 3 are positioned above the semiconductor layer 7. FIG. 4 is a schematic sectional diagram that illustrates a solid state radiation detector of the top gate structure. Note that in FIG. 4, elements which are the same as those illustrated in FIG. 1 are denoted with the same reference numerals, and detailed descriptions thereof are omitted unless particularly necessary.

The solid state radiation detector illustrated in FIG. 4 is constituted by a radiation photoconductive layer 1 that generates electric charges when irradiated by radiation, a semiconductor layer 7 of an active matrix layer 10 formed on the radiation photoconductive layer 1, and gate electrodes 3 provided on the semiconductor layer 7. Source electrodes 8 and drain electrodes 9 are configured to contact the semiconductor layer by penetrating through a gate insulating film 5and an interlayer insulating film 11, which are provided on the semiconductor layer 7.

The solid state radiation detector having the top gate structure illustrated in FIG. 4 is formed by forming a film of a-Si or the like by the CVD method or the like to a thickness of approximately 40 nm on the radiation photoconductive layer, to form the semiconductor layer 7. Next, the gate insulting film 5 is formed as a film to a desired thickness by the CVD method or the like. Therafter, the gate electrodes 3 are formed by forming metal films of Ta, AL, or the like by sputtering vapor deposition at predetermined positions. After forming the gate electrodes 3, an acrylic resin having photosensitive properties, for example, is formed as a film to cover the gate electrodes 3, to form the interlayer insulating layer 11.

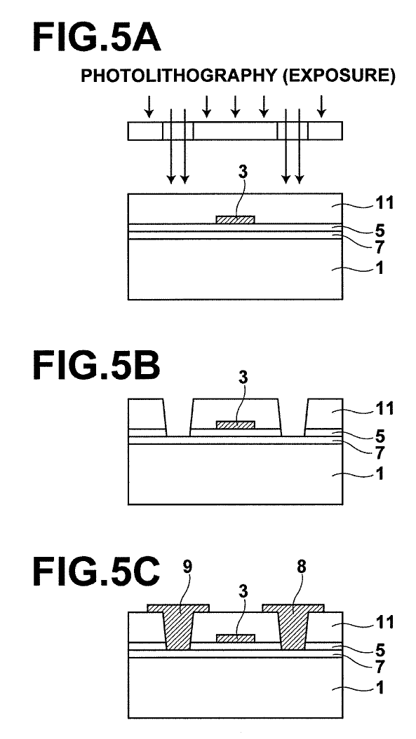

Next, the source electrodes 8 and the drain electrodes 9 are provided. These steps will be described with reference to FIGS. 5A through 5C. First, a photo mask for photolithography is prepared. The photo mask is fixed after being positioned at positions at which the source electrodes 8 and the drain electrodes 9 are to be provided. Then, photolithography (exposure) is performed (FIG. 5A). Thereafter, holes are formed by etching, using an organic solvent (FIG. 5B). The holes which are formed are tapered, but the tapers can be formed by optimizing post baking conditions after development, in the case that the photosensitive interlayer insulating film is to be selected. The source electrodes 8 and the drain electrodes 9 by the vapor deposition method and by patterning the vapor deposited materials into desired shapes such that the source electrodes 8 and the drain electrodes 9 contact the semiconductor layer 7, after the holes are formed (FIG. 5C).

Radiation detecting systems, in which solid state radiation detectors such as that described above and an image memory that functions as a memory means for recording image signals output from the detectors, and solid state radiation detecting cassettes, in which solid state radiation detectors and an image memory that functions as a memory means for recording image signals output from the detectors as embodiments of the radiation detecting systems, are known in the field of radiation imaging for medical diagnosis and the like. The solid state radiation detecting cassettes enable radiation imaging with high degrees of freedom, for cases in which radiation images of a patient who is not ambulatory are to be obtained, for example. In these cases, a solid state radiation detecting cassette maybe placed beneath the portion of the patient to be imaged, and a radiation source of a radiation image information recording apparatus is moved to a position that faces the solid state radiation detecting cassette with the patient interposed therebetween. The solid state radiation detector which is produced by the manufacturing method of the present invention can realize light weight, as described above. Therefore, in the case that the solid state radiation detector of the present invention is housed in a casing, it become easy to carry, and a radiation detecting cassette superior in portability can be realized.

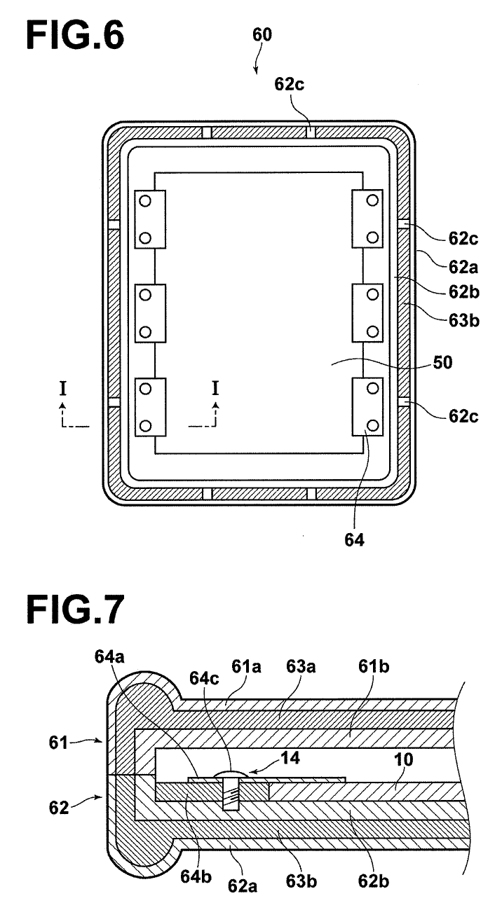

FIG. 6 is a plan view of a solid state radiation detecting cassette 60 according to a second embodiment of the present invention, with an upper shell half omitted. FIG. 7 is a sectional view of the radiation detecting cassette 60 of FIG. 6, taken along line I-I, including the upper shell half.

The radiation detecting cassette 60 is equipped with: a casing constituted by an upper shell half 61 and a lower shell half 62; a solid state radiation detector 50 (the solid state radiation detector illustrated in FIG. 1); an electric circuit (not shown) for detecting current that flows from the solid state radiation detector 50 to obtain image signals; a flexible circuit board (not shown) that connects the solid state radiation detector 50 to the electric circuit; and a power source (not shown). The solid state radiation detector 50, the electric circuit, the flexible circuit board, and the power source are housed within the casing.

The lower shell half 62 is constituted by: a substantially parallelepiped outer shell 62a having an open surface; a substantially parallelepiped inner shell 62b having an open surface; and linking members 62c which are provided between the inner side wall of the outer shell 62a and the outer side wall of the inner shell 62b. The two ends of the linking members 62c are fixed to the inner side wall of the outer shell 62a and the outer side wall of the inner shell 62b, respectively. The space between the outer shell 62a and the inner shell 62b is filled with a shock absorbing material 63b. The upper shell half 61 is of a similar construction.

The upper shell half 61 and the lower shell half 62 are both made from materials that transmit radiation. The inner shells 61b and 62b may be molded as shells having a thickness of 1 mm to 3 mm from an injection molding resin material such as ABS and polycarbonate. Alternatively, the inner shells 61b and 62b may be molded from a metal such as aluminum and a magnesium alloy. In the case that static electricity shielding effects are desired, the inner shells 61b and 62b are preferably molded from a metal material, or metal films may be formed on the inner surfaces of molded resin inner shells by plating or the like.

The linking members 62c (although not shown in the drawings, similar linking members are provided in the upper shell half 61 as well) function as restricting members that restrict movement of the inner shells 61b and 62b with respect to the outer shells 61a and 62a. Therefore, it is necessary for the material of the linking members 61c and 62c to have a certain degree of rigidity. However, it is not preferable for the material of the linking members 61c and 62c to be more rigid than necessary, from the viewpoint of shock absorption. For this reason, it is preferable for the material of the linking members 61c and 62c to be more rigid than the shock absorbing materials 63a and 63b but to have a degree of elasticity which is capable of absorbing a certain degree of shock. Examples of such a material include: hard rubber; soft plastic; fluorine resin; and polyacetal resin.

Viscoelastic materials such as soft rubber and gel, or foamed materials such as Styrofoam and urethane foam may be employed as the shock absorbing materials 63a and 63b.

The outer shells 61a and 62a of the upper and lower shell halves 61 and 62 are both formed by easily deformable resins having plasticity. Therefore, when shocks are applied thereto, the shocks can be effectively absorbed by deformation of the outer shells 61a and 62b. Further, as illustrated in FIG. 7, the outer peripheral portions of the main surfaces of the outer shells 61a and 62a are formed as ridges that protrude toward the exterior. Therefore, when shocks are applied to the main surfaces of the radiation detecting cassette, these shocks can be effectively absorbed.

The solid state radiation detector 50 is held by a holding portion 64 which is fixed to the inner shell 62b of the lower shell half 62. The holding portion 64 is constituted by: a spacer 64b of substantially the same height as the solid state radiation detector 50 and having a hole of approximately the same size as the solid state radiation detector 50 at the center thereof; holding members 64a which are placed on the upper surface of the solid state radiation detector 50; and screws 64c. The spacer 64b and the holding members 64a are placed on the inner shell 62b in this order, and the screws 64c fix the holding members 64a and the spacer 64b to the inner shell 62b.

By adopting the structure described above, the casing that houses the solid state radiation detector 50 itself has shock absorbing properties. Therefore, it becomes possible to rigidly fix the solid state radiation detector 50 to the inner shell 62b of the casing. Accordingly, the positional accuracy of the solid state radiation detector 50 within the casing can be improved, and flexing of the solid state radiation detector 50 due to its own weight and deformation of materials can be prevented. In addition, it is not necessary for the solid state radiation detector 50 to utilize a heavy substrate such as a glass substrate. Therefore, when the solid state radiation detector 50 is housed within a casing, a lightweight radiation detecting cassette which is superior in portability can be realized.

Note that in the embodiment described above, the casing was constituted by outer and inner shells that covered the entire solid state radiation detector completely. However, the radiation detecting cassette of the present invention is not limited to this configuration, and the outer and inner shells may be provided only around the periphery or only at the corners of the cassette.

What is claimed is:

1. A method for manufacturing a solid state radiation detector of the present invention is a method for manufacturing a solid state radiation detector having an active matrix layer, in which a great number of reading elements are arranged, and a radiation photoconductive layer that generates electric charges when irradiated by electromagnetic waves that bear image information, provided such that the electric charges are read out by the active matrix layer, characterized by:
the active matrix layer being formed directly on the radiation photoconductive layer.

2. A method for manufacturing a solid state radiation detector as defined in claim 1, wherein:
the radiation photoconductive layer is formed by a composite inorganic material.

3. A method for manufacturing a solid state radiation detector as defined in claim 2, wherein:
the composite inorganic material is one of CdTe and CdZnTe.

4. A method for manufacturing a solid state radiation detector as defined in claim 2, wherein:
the composite inorganic material is at least one of: Bi₁₂SiO₂₀; Bi₁₂GeO₂₀; and Bi₁₂TiO₂₀.

5. A radiation imaging system, characterized by housing a solid state radiation detector which is produced by the manufacturing method defined in claim 1.

6. A radiation imaging system, characterized by housing a solid state radiation detector which is produced by the manufacturing method defined in claim 2.

7. A radiation imaging system, characterized by housing a solid state radiation detector which is produced by the manufacturing method defined in claim 3.

8. A radiation imaging system, characterized by housing a solid state radiation detector which is produced by the manufacturing method defined in claim 4.

9. A solid state radiation detecting cassette, characterized by housing a solid state radiation detector which is produced by the manufacturing method defined in claim 1.

10. A solid state radiation detecting cassette, characterized by housing a solid state radiation detector which is produced by the manufacturing method defined in claim 2.

11. A solid state radiation detecting cassette, characterized by housing a solid state radiation detector which is produced by the manufacturing method defined in claim 3.

12. A solid state radiation detecting cassette, characterized by housing a solid state radiation detector which is produced by the manufacturing method defined in claim 4.
